(19) United States
(12) Patent Application Publication
(10) Pub. No.: US 2025/0212432 A1
(43) Pub. Date: Jun. 26, 2025

(54) SEMICONDUCTOR DEVICE AND RADIO FREQUENCY POWER AMPLIFIER

(71) Applicant: Murata Manufacturing Co., Ltd., Kyoto-fu (JP)

(72) Inventors: Kenji SASAKI, Nagaokakyo-shi (JP); Shinnosuke TAKAHASHI, Nagaokakyo-shi (JP); Satoshi GOTO, Nagaokakyo-shi (JP)

(73) Assignee: Murata Manufacturing Co., Ltd., Kyoto-fu (JP)

(21) Appl. No.: 19/081,659

(22) Filed: Mar. 17, 2025

Related U.S. Application Data
(63) Continuation of application No. PCT/JP2023/030322, filed on Aug. 23, 2023.

(30) Foreign Application Priority Data
Sep. 20, 2022 (JP) 2022-149477

(51) Int. Cl. H10D 10/80; H01L 23/00; H01L 23/48; H01L 25/16; H03F 3/213; H03F 3/24; H10D 64/23; H10D 64/27; H10D 84/60

(52) U.S. Cl. CPC H10D 10/841; H01L 23/481; H01L 24/16; H03F 3/213; H03F 3/245; H10D 64/231; H10D 64/281; H10D 84/615; H01L 25/16; H01L 2224/16058; H01L 2224/16059; H01L 2224/16227; H01L 2224/16238; H01L 2924/13051; H01L 2924/1421; H03F 2200/451

(57) ABSTRACT

A transistor includes a collector layer, a base layer, and an emitter layer that are laminated in order on an upper surface of a substrate. Four or more emitter electrodes are electrically coupled to the emitter layer. A base electrode includes two or more base fingers electrically coupled to the base layer. A collector electrode is electrically coupled to the collector layer. The emitter electrodes and the base fingers each have a shape elongated in a first direction in the upper surface of the substrate. The emitter electrode and the base finger are side by side in a second direction orthogonal to the first direction in the upper surface of the substrate. The emitter electrodes are respectively at both ends in the second direction of a row of the four or more emitter electrodes and the two or more base fingers disposed side by side in the second direction.

### CROSS-REFERENCE TO RELATED APPLICATIONS

This application claims benefit of priority to International Patent Application No. PCT/JP2023/030322, filed Aug. 23, 2023, and to Japanese Patent Application No. 2022-149477, filed Sep. 20, 2022, the entire contents of each are incorporated herein by reference.

### BACKGROUND

### Technical Field

The present disclosure relates to a semiconductor device and a radio frequency power amplifier.

### Background Art

A heterojunction bipolar transistor in which an emitter layer is formed of multiple strip-shaped emitter fingers is publicly known as described, for example, in Japanese Unexamined Patent Application Publication No. 5-190563. Finger portions (base fingers) of a base electrode are disposed on both sides of each of the emitter fingers in a width direction. The emitter finger and the base finger are disposed so as to be encompassed in a junction interface of a collector layer and a base layer in plan view.

When collector-base junction capacitance Cbc increases, gain of a transistor lowers. In order to mitigate lowering of the gain, a ratio of an area of the collector-base junction interface to an area of an emitter-base junction interface is preferably made small.

### SUMMARY

In a configuration in which base fingers are disposed on both sides of each of multiple emitter fingers as described in Japanese Unexamined Patent Application Publication No. 5-190563, the emitter finger is disposed only on one side of the outermost base finger. Since no emitter finger faces an edge of an outer side portion of the outermost base finger, no base current flows from this edge toward the emitter finger. However, from a viewpoint of a manufacturing process, a junction interface of the collector layer and the base layer need be widened so that the edge of the base finger, which does not function as a starting point of a base current to flow, is also encompassed in the junction interface of the collector layer and the base layer in plan view. The configuration above is not preferable from a viewpoint of reducing the collector-base junction capacitance Cbc.

In addition to the reduction of the collector-base junction capacitance, an increase of a breakdown withstand voltage is required.

Accordingly, the present disclosure provides a semiconductor device capable of reducing the collector-base junction capacitance and making the breakdown withstand voltage higher. Also, the present disclosure provides a radio frequency power amplifier using the semiconductor device.

According to an aspect of the present disclosure, a semiconductor device as follows is provided. The semiconductor device includes a substrate; a transistor including a collector layer, a base layer, and an emitter layer that are laminated in order on an upper surface being one side surface of the substrate; four or more emitter electrodes electrically coupled to the emitter layer; a base electrode including two or more base fingers electrically coupled to the base layer; and a collector electrode electrically coupled to the collector layer. The emitter electrodes and the base fingers each have a shape elongated in a first direction in the upper surface of the substrate, the emitter electrode and the base finger are disposed side by side in a second direction orthogonal to the first direction in the upper surface of the substrate, at both ends in the second direction of a row in which the four or more emitter electrodes and the two or more base fingers are disposed side by side in the second direction, the emitter electrodes are disposed respectively, an inter-base finger region is a region between the two base fingers adjacent to each other in the second direction, and the two emitter electrodes being side by side in the second direction are disposed in at least the one inter-base finger region, and when a ratio of an area of the emitter electrode in plan view to a length of an edge of the emitter electrode facing the one or two base fingers disposed adjacent to each of the multiple emitter electrodes is defined as an area to facing length ratio, a difference between a maximum value and a minimum value of the area to facing length ratio of each of the multiple emitter electrodes is 20% or less of an average value of the area to facing length ratio.

According to another aspect of the present disclosure, a semiconductor device as follows is provided. The semiconductor device includes: a transistor including a collector layer, a base layer, and an emitter layer laminated in order on an upper surface being one side surface of a substrate; three emitter electrodes electrically coupled to the emitter layer; a base electrode including two base fingers electrically coupled to the base layer; and a collector electrode electrically coupled to the collector layer. The emitter electrodes and the base fingers each have a shape elongated in a first direction in the upper surface of the substrate, the three emitter electrodes and the two base fingers are disposed in a second direction orthogonal to the first direction in the upper surface of the substrate in an order of the emitter electrode, the base finger, the emitter electrode, the base finger, and the emitter electrode, when a ratio of an area of the emitter electrode in plan view to a length of an edge of the emitter electrode facing the one or two base fingers disposed adjacent to each of the multiple emitter electrodes is defined as an area to facing length ratio, a difference between a maximum value and a minimum value of the area to facing length ratio of each of the multiple emitter electrodes is 20% or less of an average value of the area to facing length ratio, and in plan view, a ratio of a dimension in the second direction to a dimension in the first direction of a minimum encompassing rectangle that encompasses the three emitter electrodes is 0.5 or more and 2 or less (i.e., from 0.5 to 2).

According to another aspect of the present disclosure, a radio frequency power amplifier as follows is provided. The radio frequency power amplifier includes the multiple semiconductor devices disposed side by side in the second direction on the upper surface of the substrate; an emitter wiring that couples the emitter electrodes of the multiple semiconductor devices; a radio frequency signal input wiring; and an input capacitor that couples the base electrode of each of the multiple semiconductor devices and the radio frequency signal input wiring. The collector electrodes of the multiple semiconductor devices are continuous with each other.

In a row of the emitter electrodes and the base finger disposed side by side in the second direction, the emitter electrodes are disposed at both ends in the second direction, respectively, thereby the collector-base junction capacitance can be reduced relative to the emitter-base junction capacitance, as compared with a configuration in which the base fingers are disposed at both ends. By setting the difference between the maximum value and the minimum value of the area to facing length ratio of each of the multiple emitter electrodes to be 20% or less of the average value of the area to facing length ratio, deterioration of uniformity of emitter current density is mitigated, and as a result, the breakdown withstand voltage can be made higher.

### BRIEF DESCRIPTION OF THE DRAWINGS

FIG. 1A is a diagram illustrating a disposition of constituent elements of a semiconductor device according to a first embodiment in plan view, and FIG. 1B is a sectional view taken along a dashed-and-dotted line 1B-1B in FIG. 1A;

FIG. 2A and FIG. 2B each are a plan view illustrating a disposition of a base electrode, emitter electrodes and collector electrodes of two samples to be targets of an evaluation experiment;

FIG. 3 is a graph illustrating a measurement result of a breakdown boundary of each of the samples illustrated in FIG. 2A and FIG. 2B;

FIG. 4A and FIG. 4B each are a diagram illustrating a disposition of constituent elements of a semiconductor device according to a comparative example in plan view;

FIG. 5 is a diagram illustrating a disposition of constituent elements of a semiconductor device according to a comparative example in plan view;

FIG. 6A and FIG. 6B each are a schematic diagram illustrating a positional relationship of one emitter electrode and one base finger adjacent thereto in plan view;

FIG. 7A and FIG. 7B each are a plan view illustrating a disposition and shapes of four emitter electrodes;

FIG. 8 is a diagram illustrating a disposition of constituent elements of a semiconductor device according to a second embodiment in plan view;

FIG. 9A is a diagram illustrating a disposition of constituent elements of a semiconductor device according to a third embodiment in plan view, and FIG. 9B is a sectional view taken along a dashed-and-dotted line 9B-9B in FIG. 9A;

FIG. 10A is a diagram illustrating a disposition of constituent elements of a semiconductor device according to a fourth embodiment in plan view, and FIG. 10B is a sectional view taken along a dashed-and-dotted line 10B-10B in FIG. 10A;

FIG. 11 is a schematic diagram illustrating a positional relationship of an emitter electrode and a base finger of the semiconductor device according to the fourth embodiment in plan view;

FIG. 12 is a diagram illustrating a disposition of constituent elements of a radio frequency power amplifier according to a fifth embodiment in plan view;

FIG. 13 is a sectional view taken along a dashed-and-dotted line 13-13 in FIG. 12;

FIG. 14 is an equivalent circuit diagram of one cell of the radio frequency power amplifier according to the fifth embodiment;

FIG. 15 is a diagram illustrating a disposition of constituent elements of a radio frequency power amplifier according to a sixth embodiment in plan view;

FIG. 16 is a diagram illustrating a disposition of constituent elements of a radio frequency power amplifier according to a seventh embodiment in plan view;

FIG. 17 is a sectional view taken along a dashed-and-dotted line 17-17 in FIG. 16;

FIG. 18 is a block diagram of a radio frequency amplification circuit according to an eighth embodiment;

FIG. 19 is a diagram illustrating a disposition of constituent elements in a substrate of the radio frequency amplification circuit according to the eighth embodiment; and

FIG. 20 is a schematic sectional view of a radio frequency front-end module according to the eighth embodiment.

### DETAILED DESCRIPTION

### First Embodiment

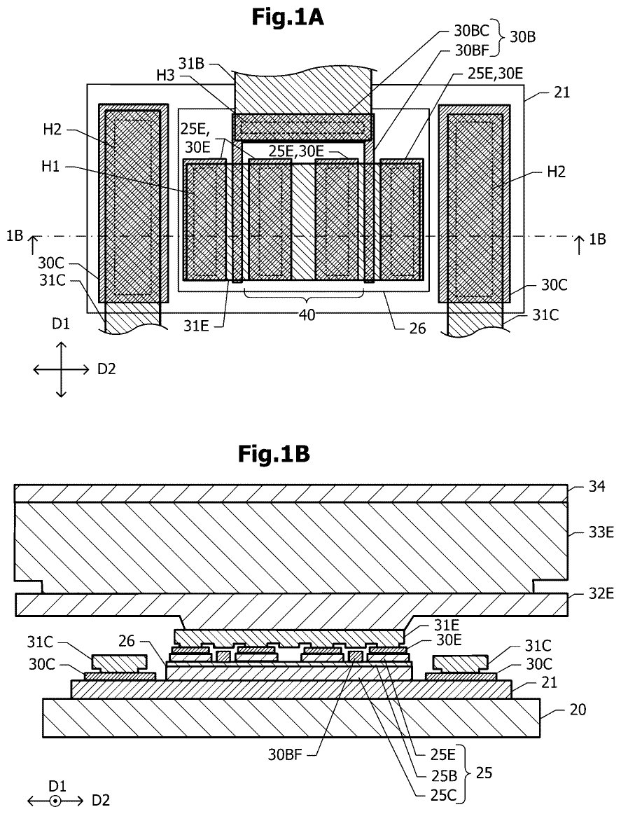

A semiconductor device according to a first embodiment will be described with reference to FIG. 1A to FIG. 5.

FIG. 1A is a diagram illustrating a disposition of constituent elements of the semiconductor device according to the first embodiment in plan view, and FIG. 1B is a sectional view taken along a dashed-and-dotted line 1B-1B in FIG. 1A. A sub-collector layer 21 having n-type conductivity is disposed in a partial region of an upper surface which is one side surface of a substrate 20 made of a semi-insulating semiconductor. In the present description, viewing the upper surface of the substrate 20 from a direction perpendicular thereto is referred to as plan view. In FIG. 1A, an electrode in contact with a semiconductor region is hatched with relatively dark lines rising to the right, and a wiring of a first layer on the electrode is hatched with relatively light lines falling to the right.

A transistor 25 is disposed on a partial region of the sub-collector layer 21. The transistor 25 includes a collector layer 25C, a base layer 25B, and four emitter layers 25E laminated in order from the sub-collector layer 21. For example, the sub-collector layer 21 and the collector layer 25C each are formed of n-type GaAs, the base layer 25B is formed of p-type GaAs, and the emitter layer 25E is formed of n-type InGaP. That is, the transistor 25 is a heterojunction bipolar transistor.

A layered structure of the collector layer 25C and the base layer 25B is referred to as a collector mesa 26. Each of the four emitter layers 25E has a shape elongated in one direction in plan view. In the upper surface of the substrate 20, a longitudinal direction of the emitter layer 25E is referred to as a first direction D1, and a direction orthogonal to the first direction D1 is referred to as a second direction D2.

The four emitter layers 25E are disposed side by side in the second direction D2 at intervals to each other. Emitter electrodes 30E are disposed on the emitter layers 25E, respectively. In plan view, the emitter electrode 30E has substantially the same shape and size as the emitter layer 25E, and substantially overlaps with the emitter layer 25E. That is, an area of the emitter electrode 30E in plan view can be considered to be substantially equal to an area of an emitter-base junction interface. The emitter electrode 30E is electrically coupled to the emitter layer 25E. Here, “electrically coupled” means being coupled substantially in accordance with Ohm's law. In the example illustrated in FIG. 1B, exposed is a crystal surface of the base layer 25B in a region where the emitter layer 25E is not disposed. However, a ledge structure in which the crystal surface is not exposed may be adopted.

Two collector electrodes 30C are disposed on the upper surface of the sub-collector layer 21 so as to sandwich the collector mesa 26 in the second direction D2 in plan view. The collector electrode 30C is electrically coupled to the collector layer 25C via the sub-collector layer 21.

A base electrode 30B includes two base fingers 30BF and a base contact portion 30BC that couples the two base fingers 30BF. The base electrode 30B is electrically coupled to the base layer 25B. In plan view, the base fingers 30BF each have a shape elongated in the first direction D1 and are disposed side by side in the second direction D2. That is, the four emitter electrodes 30E and the two base fingers 30BF are disposed side by side in the second direction D2.

A region between the two base fingers 30BF is referred to as an inter-base finger region 40. In a row constituted of the four emitter electrodes 30E and the two base fingers 30BF, each of the two emitter electrodes 30E is disposed at both ends in the second direction D2, and the other two emitter electrodes 30E being side by side in the second direction D2 are disposed in one inter-base finger region 40.

The base contact portion 30BC couples both ends of the two base fingers 30BF. The four emitter electrodes 30E and the base electrode 30B are encompassed in the collector mesa 26 in plan view.

A collector wiring 31C, an emitter wiring 31E, and a base wiring 31B are disposed in a wiring layer of the first layer. Part of the collector wiring 31C overlaps with the collector electrode 30C in plan view. The collector wiring 31C is coupled to the collector electrode 30C through an opening H2 disposed in a region overlapping with the collector electrode 30C. The collector wiring 31C extends from the region overlapping with the collector electrode 30C toward one side in the second direction D2 (lower side in FIG. 1A).

A portion of the base wiring 31B overlaps with the base contact portion 30BC of the base electrode 30B in plan view. The base wiring 31B is coupled to the base contact portion 30BC through an opening H3 disposed in a region overlapping with the base contact portion 30BC. The base wiring 31B extends from the region overlapping with the base contact portion 30BC toward one side in the second direction D2 (upper side in FIG. 1A). The collector wiring 31C and the base wiring 31B extend in opposite directions.

The emitter wiring 31E is disposed so as to overlap with the four emitter electrodes 30E in plan view. The emitter wiring 31E is coupled to the four emitter electrodes 30E through openings H1 respectively disposed in regions overlapping with the four emitter electrodes 30E.

An emitter wiring 32E is disposed in a wiring layer of a second layer. The emitter wiring 32E of the second layer overlaps with the emitter wiring 31E of the first layer in plan view, and is coupled to the emitter wiring 31E of the first layer. An outer coupling terminal 33E for the emitter is disposed on the emitter wiring 32E of the second layer, and solder 34 is placed thereon. A Cu pillar bump, for example, is used as the outer coupling terminal 33E. Note that, instead of the Cu pillar bump, an Au bump, a solder ball bump, or the like may be used.

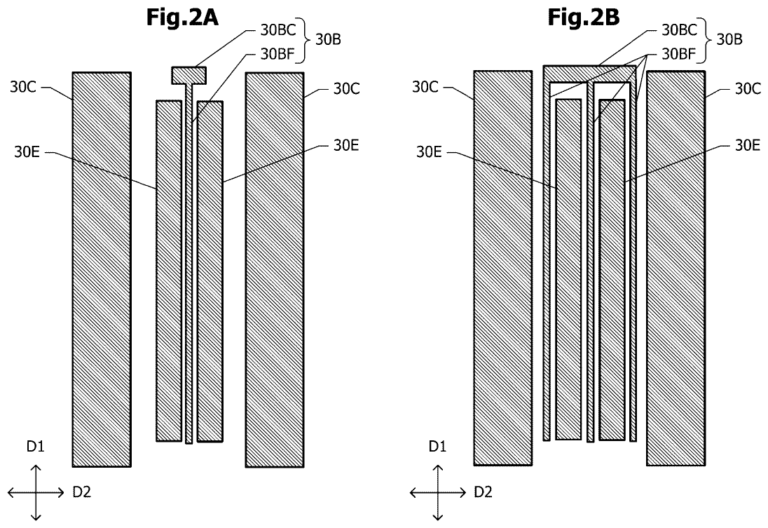

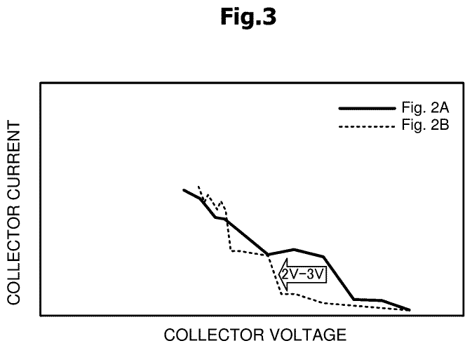

Next, an evaluation experiment conducted by the inventors will be described with reference to FIG. 2A to FIG. 3. Two samples having different shapes of the base electrode 30B were fabricated, and a breakdown withstand voltage of each sample was measured.

FIG. 2A and FIG. 2B each are a plan view illustrating a disposition of the base electrode 30B, the emitter electrodes 30E, and the collector electrodes 30C of two samples. In FIG. 2A and FIG. 2B, these electrodes are hatched. In each of the samples, the base finger 30BF of the base electrode 30B and the emitter electrode 30E each have a shape elongated in the first direction D1, and the two emitter electrodes 30E are disposed side by side in the second direction D2.

In the sample illustrated in FIG. 2A, the base finger 30BF is disposed between the two emitter electrodes 30E, and the base finger 30BF is not disposed in an outer side portion of the two emitter electrodes 30E. In the sample illustrated in FIG. 2B, three base fingers 30BF are disposed, and the emitter electrodes 30E are respectively disposed between the two base fingers 30BF adjacent to each other in the second direction D2. In each of the samples, the base contact portion 30BC is coupled to one end portion of the base finger 30BF.

That is, in the sample illustrated in FIG. 2A, the base finger 30BF is disposed only on one side of each of the emitter electrodes 30E in a width direction (second direction D2). In the sample illustrated in FIG. 2B, the base fingers 30BF are disposed on both sides of each of the emitter electrodes 30E in the width direction.

FIG. 3 is a graph illustrating a measurement result of a breakdown withstand voltage of each of the samples illustrated in FIG. 2A and FIG. 2B. A horizontal axis represents a collector voltage, and a vertical axis represents a collector current. In FIG. 3, a solid line indicates a breakdown boundary of the sample illustrated in FIG. 2A, and a broken line indicates a breakdown boundary of the sample illustrated in FIG. 2B. Obtained is a result in which the breakdown boundary on a high voltage side of the sample in FIG. 2B is lower than the breakdown boundary on a high voltage side of the sample in FIG. 2A by approximately 2 V to 3 V.

With the evaluation experiment above, it was confirmed that the breakdown withstand voltage lowers when the base fingers 30BF are disposed on both sides of the emitter electrode 30E.

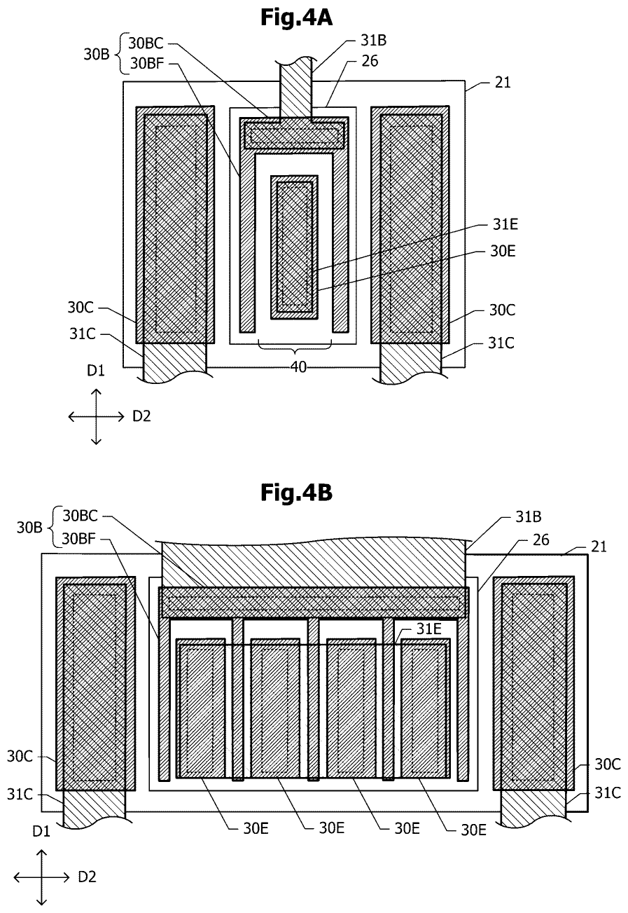

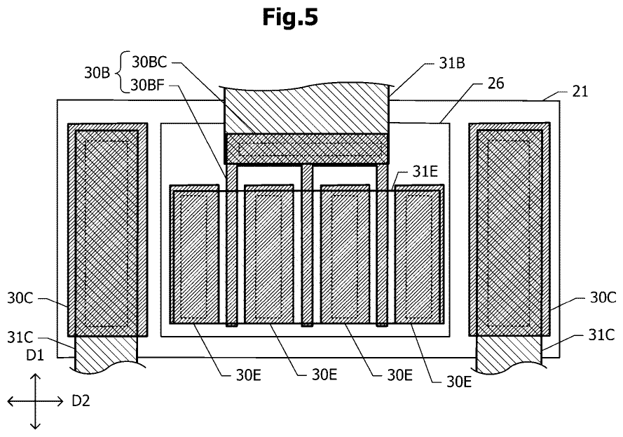

Next, excellent effects of the first embodiment will be described in comparison with a semiconductor device according to a comparative example illustrated in each of FIG. 4A to FIG. 5. FIG. 4A, FIG. 4B, and FIG. 5 each are a diagram illustrating a disposition of constituent elements of the semiconductor device according to the comparative example in plan view. In FIG. 4A, FIG. 4B, and FIG. 5, as in FIG. 1A, an electrode in contact with a semiconductor region is hatched with relatively dark lines rising to the right, and a wiring of a first layer on the electrode is hatched with relatively light lines falling to the right. The constituent elements of the semiconductor device according to each of the comparative examples illustrated in FIG. 4A, FIG. 4B, and FIG. 5 are denoted by the same signs as the corresponding constituent elements of the semiconductor device according to the first embodiment illustrated in FIG. 1A.

In the comparative example illustrated in FIG. 4A, two base fingers 30BF are disposed in the collector mesa 26 in plan view, and one emitter electrode 30E is disposed in the inter-base finger region 40.

A collector-base junction area is denoted as Scb, and an emitter-base junction area is denoted as Seb. Although it is ideal that a ratio of the collector-base junction area Scb to the emitter-base junction area Seb (Scb/Seb) is 1, Scb/Seb is larger than 1 because it is necessary to ensure a region to dispose the base finger 30BF. In order to make Scb/Seb closer to 1, it is preferable to make an area of a region occupied by the base finger 30BF smaller than the emitter-base junction area Seb. In the comparative example illustrated in FIG. 4B, the five base fingers 30BF are disposed for the four emitter electrodes 30E. As a result, Scb/Seb of the comparative example illustrated in FIG. 4B is smaller than Scb/Seb of the comparative example illustrated in FIG. 4A. Since collector-base junction capacitance Cbc is proportional to an area of the collector mesa 26, a ratio of the collector-base junction capacitance Cbc to an area of the emitter electrode 30E becomes small.

As described above, the comparative example illustrated in FIG. 4B is more preferable than the comparative example illustrated in FIG. 4A, from a viewpoint of reducing a ratio of an area of a collector-base junction interface to the area of the emitter electrode 30E in plan view. However, in the comparative example illustrated in FIG. 4B, since the base fingers 30BF are disposed on both sides of each of the emitter electrodes 30E in the width direction, the breakdown withstand voltage lowers from the result of the evaluation experiment described with reference to FIG. 2A to FIG. 3.

In the comparative example illustrated in FIG. 5, the two outermost base fingers 30BF of the comparative example illustrated in FIG. 4B are removed. In the comparative example illustrated in FIG. 5, three base fingers 30BF are disposed for four emitter electrodes 30E, and the number of base fingers 30BF for one emitter electrode 30E is smaller than that in the case of FIG. 4B, so that the ratio of the area of the collector-base junction interface to the area of the emitter electrode 30E in plan view is smaller than that in the comparative example illustrated in FIG. 4B.

However, in the comparative example illustrated in FIG. 5, the base fingers 30BF are disposed only on one side of each of the two outermost emitter electrodes 30E in the width direction, and the base fingers 30BF are disposed on both sides in the width direction of each of the other two emitter electrodes 30E. As a result, operating conditions vary among the emitter electrodes 30E, and variation in emitter current density increases.

The variation in the emitter current density causes variation in a heat generation amount among the emitter layers 25E immediately below the emitter electrodes 30E (FIG. 1B), and thermal uniformity is deteriorated. As a result, thermal runaway is likely to occur, and the breakdown withstand voltage lowers.

In contrast, in the first embodiment (FIG. 1A), when each of the emitter electrodes 30E is focused on, the base finger 30BF is disposed adjacent to only one side of the emitter electrode 30E in the width direction. As a result, variation in the operating conditions among the emitter electrodes 30E is reduced, and the variation in the emitter current density is also reduced. As a result, the thermal uniformity is maintained and the thermal runaway is less likely to occur.

Further, in the first embodiment (FIG. 1A), for all the emitter electrodes 30E, the base finger 30BF is disposed adjacent to only one side in the width direction of each of the emitter electrodes 30E, so that the emitter electrodes 30E each operate under substantially the same operating condition as the emitter electrode 30E of the semiconductor device according to the comparative example illustrated in FIG. 2A. As a result, the breakdown withstand voltage can be made higher as illustrated in FIG. 3, as compared with the configuration in which the base fingers 30BF are disposed on both sides in the width direction of each of the emitter electrodes 30E.

Further, in the first embodiment (FIG. 1A), two base fingers 30BF are disposed for four emitter electrodes 30E. That is, the number of base fingers 30BF for one emitter electrode 30E is ½, which is smaller than that of the comparative example illustrated in FIG. 4B or FIG. 5. As a result, the ratio of the area of the collector-base junction interface to the area of the emitter electrode 30E in plan view can be made smaller. The first embodiment is superior to the comparative example illustrated in FIG. 4B or FIG. 5 from a viewpoint of reducing the collector-base junction capacitance Cbc relative to the area of the emitter electrode 30E in plan view, as well. With this, lowering in gain due to the collector-base junction capacitance Cbc can be mitigated.

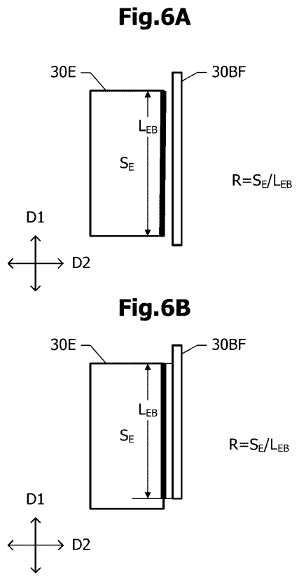

Next, with reference to FIG. 6A and FIG. 6B, a preferable shape and a dimension of each of the four emitter electrodes 30E will be described. FIG. 6A and FIG. 6B each are a schematic diagram illustrating a positional relationship of one emitter electrode 30E and one base finger 30BF adjacent thereto in plan view.

In the example illustrated in FIG. 6A, the emitter electrode 30E is included in a range of the first direction D1 in which the base finger 30BF is disposed. At this time, one side edge (edge indicated by thick solid line) parallel to the emitter electrode 30E in the first direction D1 faces the base finger 30BF over an entire length of the emitter electrode 30E. A length of the edge of the emitter electrode 30E facing the base finger 30BF is referred to as a facing length L_{EB}. The area of the emitter electrode 30E in plan view is denoted as S_{E}. Although an edge of the emitter electrode 30E parallel to the second direction D2 faces the base contact portion 30BC, since a distance between the emitter electrode 30E and the base contact portion 30BC is sufficiently larger than a distance between the emitter electrode 30E and the base finger 30BF, a length of the edge facing the base contact portion 30BC is not included in the facing length L_{BE}.

S_{E}/L_{EB} being a ratio of the area S_{E} to the facing length L_{EB} is referred to as an area to facing length ratio R. In order to mitigate the deterioration of uniformity of an operation, for example, in order to mitigate the deterioration of uniformity of the emitter current density among the multiple emitter electrodes 30E, it is preferable to reduce the variation in the area to facing length ratio R among the multiple emitter electrodes 30E. For example, a difference between the maximum value and the minimum value of the area to facing length ratio R is preferably 20% or less of an average value of the area to facing length ratio R, and more preferably 10% or less. Further, it is most preferable that all the emitter electrodes 30E have the same area to facing length ratio R. For example, it is preferable that all the emitter electrodes 30E have the same facing length L_{EB} and the same area S_{E} as well. It is to be noted that a case in which a variation in dimension within an allowable range in a manufacturing process occurs is also referred to as “the same”.

In the example illustrated in FIG. 6B, part of the emitter electrode 30E extends to an outer side portion of a range of the first direction D1 in which the base finger 30BF is disposed. That is, only part (portion indicated by thick solid line) of one side edge of the emitter electrode 30E parallel to the first direction D1 faces the base finger 30BF. A length of the portion of the one side edge of the emitter electrode 30E parallel to the first direction D1, in a range of the first direction D1 in which the base finger 30BF is disposed, corresponds to the facing length L_{EB}.

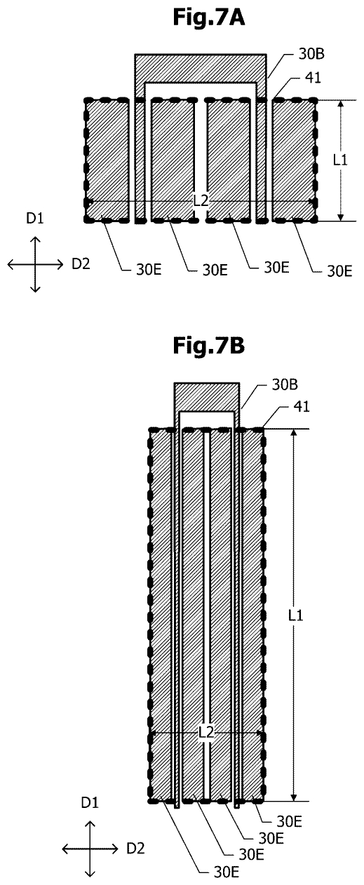

Next, a preferable disposition and shape of the emitter electrode 30E will be described with reference to FIG. 7A and FIG. 7B. FIG. 7A and FIG. 7B each are a plan view illustrating a disposition and shapes of four emitter electrodes 30E. The smallest rectangle that encompasses the four emitter electrodes 30E in plan view is referred to as a minimum encompassing rectangle 41. Usually, a pair of sides of the minimum encompassing rectangle 41 are parallel to the first direction D1, and the other pair of sides are parallel to the second direction D2. A dimension of the minimum encompassing rectangle 41 in the first direction D1 is denoted as L1, and a dimension of the minimum encompassing rectangle 41 in the second direction D2 is denoted as L2.

In the example illustrated in FIG. 7A, an aspect ratio of the minimum encompassing rectangle 41 is closer to 1 than in the example illustrated in FIG. 7B. When the aspect ratio of the minimum encompassing rectangle 41 deviates from 1, that is, when the minimum encompassing rectangle 41 is elongated, variation of temperature tends to occur in the longitudinal direction. When the variation of temperature occurs, the transistor 25 is likely to get into thermal runaway. In order to prevent the thermal runaway of the transistor 25, the minimum encompassing rectangle 41 is preferably made closer to a square. For example, a ratio of the dimension L2 in the second direction D2 to the dimension L1 in the first direction D1 of the minimum encompassing rectangle 41 is preferably 0.5 or more and 2 or less (i.e., from 0.5 to 2).

Next, a modification of the first embodiment will be described.

In the first embodiment, in one transistor 25 (FIG. 1B), the four emitter electrodes 30E and the two base fingers 30BF are disposed side by side in the second direction D2, but the number of emitter electrodes 30E may be four or more, and the number of base fingers 30BF may be two or more. At this time, the two emitter electrodes 30E and the one base finger 30BF disposed therebetween form a repetition unit, and the multiple repetition units are disposed side by side in the second direction D2. That is, the number of emitter electrodes 30E is an even number, and the number of base fingers 30BF is one half of the number of the emitter electrodes 30E.

### Second Embodiment

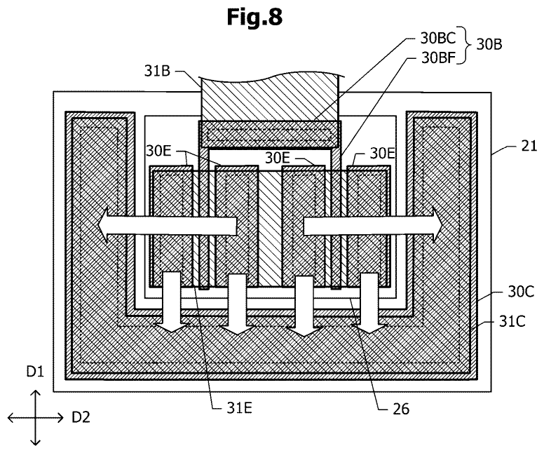

Next, a semiconductor device according to a second embodiment will be described with reference to FIG. 8. Hereinafter, a description of the common configuration with the semiconductor device according to the first embodiment described with reference to FIG. 1A to FIG. 7B will be omitted.

FIG. 8 is a diagram illustrating a disposition of constituent elements of the semiconductor device according to the second embodiment in plan view. In FIG. 8, as in FIG. 1A, an electrode in contact with a semiconductor region is hatched with relatively dark lines rising to the right, and a wiring of a first layer on the electrode is hatched with relatively light lines falling to the right.

In the first embodiment (FIG. 1A), the pair of collector electrodes 30C sandwich the collector mesa 26 in the second direction D2. In contrast, in the second embodiment, in plan view, the collector electrodes 30C surround the row of the emitter electrodes 30E and the base fingers 30BF disposed side by side in the second direction D2 in a U-shape, on both sides in the second direction D2 and one side in the first direction D1 (lower side in FIG. 8). The collector wiring 31C of the first layer also has a U-shape similarly to the collector electrode 30C.

Next, excellent effects of the second embodiment will be described.

In the second embodiment, as in the first embodiment, lowering in gain due to the collector-base junction capacitance Cbc can be mitigated.

In the first embodiment (FIG. 1A), the collector current flows from the emitter electrodes 30E to the collector electrode 30C as indicated with a horizontal arrow in FIG. 8. In contrast, in the second embodiment, the collector current flows not only in a direction of the horizontal arrow indicated in FIG. 8 but also in a direction of a vertical arrow. Thereby uniformity of the current among the multiple emitter electrodes 30E increases. As a result, thermal uniformity increases, and an effect of preventing thermal runaway and an effect of making the breakdown withstand voltage higher are more substantial than those of the first embodiment.

### Third Embodiment

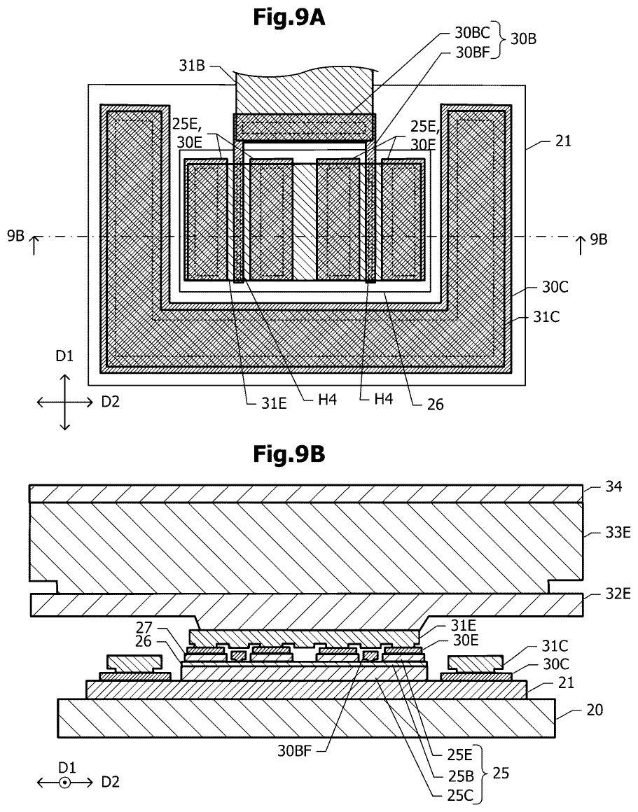

Next, a semiconductor device according to a third embodiment will be described with reference to FIG. 9A and FIG. 9B. Hereinafter, a description of the common configuration with the semiconductor device according to the first embodiment described with reference to FIG. 1A to FIG. 7B will be omitted.

FIG. 9A is a diagram illustrating a disposition of constituent elements of the semiconductor device according to the third embodiment in plan view, and FIG. 9B is a sectional view taken along a dashed-and-dotted line 9B-9B in FIG. 9A. In FIG. 9A, as in FIG. 1A, an electrode in contact with a semiconductor region is hatched with relatively dark lines rising to the right, and a wiring of a first layer on the electrode is hatched with relatively light lines falling to the right.

In the first embodiment (FIG. 1A), the entire base electrode 30B is encompassed in the collector mesa 26 in plan view. That is, the base contact portion 30BC is disposed inside the collector mesa 26 in plan view. In contrast, in the third embodiment, the base contact portion 30BC is disposed in an outer side portion of the collector mesa 26, that is, an outer side portion of a junction interface of the base layer 25B and the collector layer 25C in plan view. In this configuration, an insulating film is disposed between the base electrode 30B and the sub-collector layer 21 so that the base contact portion 30BC is not electrically coupled to the sub-collector layer 21. The insulating film is also disposed between the base layer 25B and the base finger 30BF illustrated in FIG. 9B. The insulating film is formed after the formation of the emitter electrode 30E and the collector electrode 30C.

In order to couple the base finger 30BF to the base layer 25B, openings H4 (FIG. 9A) are provided in the insulating film (not illustrated) disposed between the base finger 30BF and the base layer 25B. The base finger 30BF is electrically coupled to the base layer 25B passing through the opening H4. Since the base finger 30BF passes through the opening H4, the base finger 30BF has a T-shape in the section illustrated in FIG. 9B. The base finger 30BF intersects with a step on an outer periphery of the collector mesa 26, extends to the outer side portion of the collector mesa 26, and is coupled to the base contact portion 30BC in plan view.

Next, excellent effects of the third embodiment will be described.

In the third embodiment, as in the first embodiment, the breakdown withstand voltage can be made higher, and lowering in gain due to the collector-base junction capacitance Cbc can be mitigated. In the third embodiment, an area in plan view of the collector mesa 26 is smaller than that in the first embodiment (FIG. 1A). Thereby the collector-base junction capacitance Cbc is further reduced under a condition that the areas of the emitter electrode 30E are the same. As a result, the effect of mitigating the lowering in gain due to the collector-base junction capacitance Cbc is further enhanced.

### Fourth Embodiment

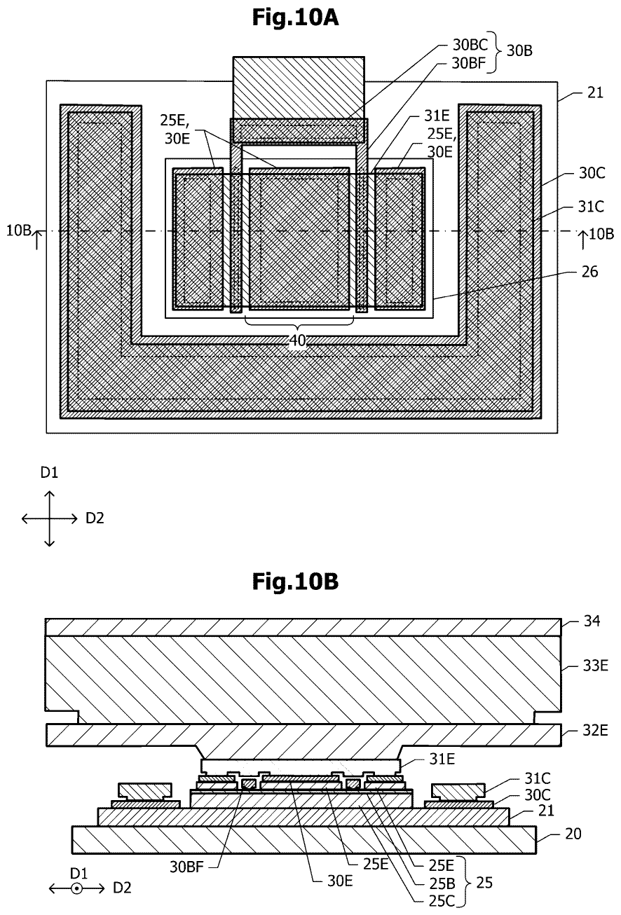

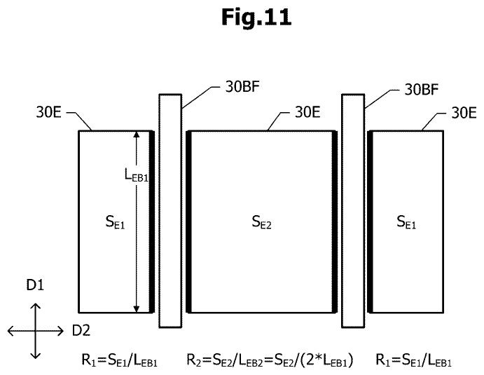

A semiconductor device according to a fourth embodiment will be described with reference to FIG. 10A to FIG. 11. Hereinafter, a description of the common configuration with the semiconductor device according to the first embodiment described with reference to FIG. 1A to FIG. 7B will be omitted.

FIG. 10A is a diagram illustrating a disposition of constituent elements of the semiconductor device according to the fourth embodiment in plan view, and FIG. 10B is a sectional view taken along a dashed-and-dotted line 10B-10B in FIG. 10A. In FIG. 10A, as in FIG. 1A, an electrode in contact with a semiconductor region is hatched with relatively dark lines rising to the right, and a wiring of a first layer on the electrode is hatched with relatively light lines falling to the right.

In the first embodiment (FIG. 1A), the two emitter electrodes 30E are disposed in the inter-base finger region 40. In contrast, in the fourth embodiment, one emitter electrode 30E and one emitter layer 25E are disposed in the inter-base finger region 40. A dimension in the second direction D2 of the emitter electrode 30E disposed in the inter-base finger region 40 is larger than a dimension in the second direction D2 of each of the emitter electrodes 30E disposed at both ends in the second direction D2. The base contact portion 30BC is disposed in the outer side portion of the collector mesa 26 in plan view, as in the semiconductor device according to the third embodiment (FIG. 9A). The three emitter electrodes 30E have the same dimension in the first direction.

Next, with reference to FIG. 11, a preferable dimension of the emitter electrode 30E will be described. FIG. 11 is a schematic diagram illustrating a positional relationship of the emitter electrode 30E and the base finger 30BF in plan view.

Among edges of the respective emitter electrodes 30E, the edge facing the base finger 30BF is indicated by a thick solid line. In the emitter electrodes 30E at both ends, one side edge out of a pair of edges parallel to the first direction D1 faces the base finger 30BF. In the emitter electrode 30E in the inter-base finger region 40, both of a pair of edges parallel to the first direction D1 face the base finger 30BF. A length of each of the pair of edges parallel to the first direction D1 is equal to a length of each of the pair of edges parallel to the first direction of the emitter electrode 30E at both ends.

A facing length of each of the emitter electrodes 30E at both ends is denoted as L_{EB1}, and an area of each of the emitter electrodes 30E at both ends in plan view is denoted as S_{E1}. The respective facing lengths L_{EB1} of the two emitter electrodes 30E at both ends are equal to each other, and the respective areas S_{E1} of the two emitter electrodes 30E at both ends are also equal to each other. An area to facing length ratio R₁ of each of the emitter electrodes 30E at both ends is calculated by the following formula.

R₁=S_{E1}/L_{EB1} (1)

A facing length of the emitter electrode 30E in the inter-base finger region 40 is denoted as L_{EB2}, and an area of the emitter electrode 30E in the inter-base finger region 40 in plan view is denoted as S_{E2}. In the emitter electrode 30E disposed in the inter-base finger region 40, since both the two edges parallel to the first direction D1 face the base fingers 30BF, respectively, the following formula holds.

L_{EB2}=2×L_{EB1} (2)

An area to facing length ratio R₂ of the emitter electrode 30E disposed in the inter-base finger region 40 is calculated by the following formula.

R₂=S_{E2}/L_{EB2}=S_{E2}/(2×L_{EB1}) (3)

As described with reference to FIG. 6A and FIG. 6B, in order to mitigate the deterioration of uniformity of an operation, for example, in order to mitigate the deterioration of uniformity of the emitter current density among the multiple emitter electrodes 30E, it is preferable to reduce the variation in the area to facing length ratios R₁ and R₂ among the multiple emitter electrodes 30E. For example, a difference between the maximum value and the minimum value of the area to facing length ratios R₁ and R₂ is preferably 20% or less of an average value of the area to facing length ratios R₁ and R₂, and more preferably 10% or less.

Further, it is most preferable that the area to facing length ratio R₂ of the emitter electrode 30E in the inter-base finger region 40 is equal to the area to facing length ratio R₁ of each of the emitter electrodes 30E at both ends. Under this optimum condition, the area S_{E2} of the emitter electrode 30E in the inter-base finger region 40 is equal to twice the area S_{E1} of each of the emitter electrodes 30E at both ends, from the formulae (1) and (3).

Next, excellent effects of the fourth embodiment will be described.

In the fourth embodiment, as in the first embodiment, the breakdown withstand voltage can be made higher, and lowering in gain due to the collector-base junction capacitance Cbc can be mitigated. In the first embodiment (FIG. 1B), a space is ensured between the two emitter electrodes 30E in the inter-base finger region 40, but in the fourth embodiment, this space need not be ensured. Thereby the area of the collector mesa 26 (FIG. 10A) can be made smaller than that in the first embodiment. As a result, the collector-base junction capacitance Cbc can further be reduced.

Next, a modification of the fourth embodiment will be described.

In the fourth embodiment, three emitter electrodes 30E are disposed, but four or more emitter electrodes 30E may be disposed. In the case above, the number of base fingers 30BF is smaller than the number of emitter electrodes 30E by one. The emitter electrodes 30E are disposed one by one in the multiple inter-base finger regions 40.

In a configuration in which the multiple inter-base finger regions 40 are disposed, there may be mixed a portion in which two emitter electrodes 30E are disposed in the inter-base finger region 40 as in the first embodiment and a portion in which one emitter electrode 30E is disposed in the inter-base finger region 40 as in the fourth embodiment.

### Fifth Embodiment

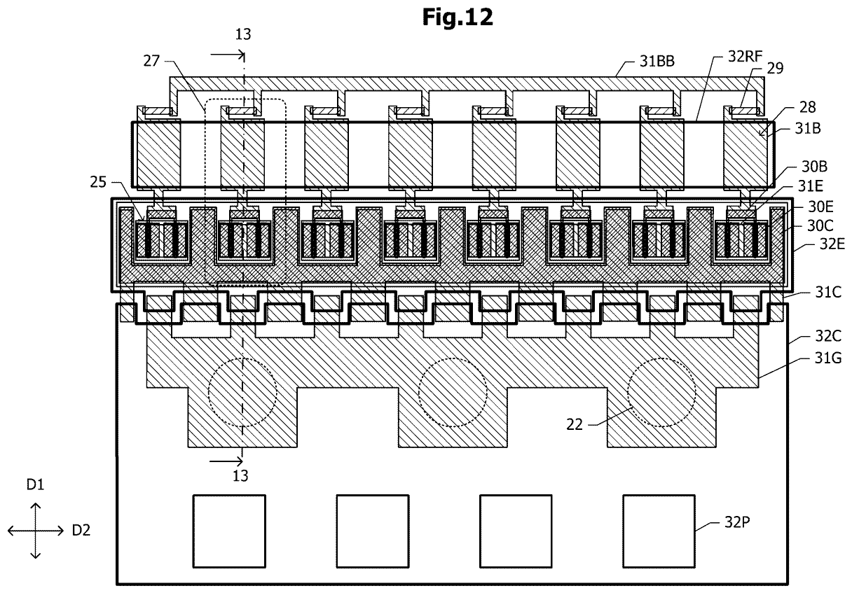

Next, a radio frequency power amplifier according to a fifth embodiment will be described with reference to FIG. 12 to FIG. 14. The radio frequency power amplifier according to the fifth embodiment includes the semiconductor device according to any one of the first to fourth embodiments.

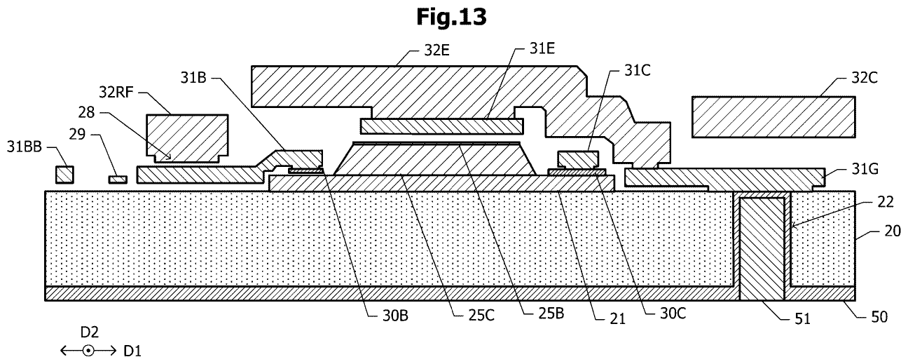

FIG. 12 is a diagram illustrating a disposition of constituent elements of the radio frequency power amplifier according to the fifth embodiment in plan view. FIG. 13 is a sectional view taken along a dashed-and-dotted line 13-13 in FIG. 12. In FIG. 12, an electrode in contact with a semiconductor region is hatched with relatively dark lines rising to the right, a wiring of a first layer is hatched with relatively light lines falling to the right, and an outline of a wiring of a second layer is indicated by a relatively thick solid line.

Multiple cells 27 are disposed side by side on an upper surface of the substrate 20 in the second direction D2. Each of the multiple cells 27 includes the transistor 25, the collector electrode 30C, the emitter electrode 30E, and the base electrode 30B of the semiconductor device according to the third embodiment (FIG. 9A and FIG. 9B). Each of the multiple cells 27 further includes an input capacitor 28 and a ballast resistance element 29. The configuration of the semiconductor device according to the first embodiment, the second embodiment, or the fourth embodiment may be adopted for each of the cells 27. The collector electrodes 30C of the two cells 27 adjacent to each other in the second direction D2 are continuous with each other.

A base wiring 31B of the first layer extends in the first direction (upward in FIG. 12) from the base contact portion 30BC (FIG. 9A) of each of the multiple cells 27. The radio frequency signal input wiring 32RF disposed in the wiring layer of the second layer intersects with the multiple base wirings 31B. A portion of the base wiring 31B overlapping with the radio frequency signal input wiring 32RF is wider than other portions, and the input capacitor 28 is formed at the overlapping portion.

One end of each of the multiple ballast resistance elements 29 overlaps with a tip of a corresponding one of the multiple base wirings 31B. The other end of the ballast resistance element 29 overlaps with part of a common base bias wiring 31BB disposed in the wiring layer of the first layer. The ballast resistance element 29 is disposed on the base wiring 31B and the base bias wiring 31BB without an interlayer insulating film interposed therebetween.

The emitter wiring 32E of the second layer encompasses the multiple transistors 25 in plan view. The emitter wiring 32E of the second layer is coupled to the multiple emitter wirings 31E of the first layer through via-holes provided in the interlayer insulating film. A ground wiring 31G of the first layer is disposed to run parallel to a cell row of the multiple cells 27. Part of the ground wiring 31G overlaps with part of the emitter wiring 32E of the second layer, and both are coupled to each other at an overlapping portion.

Multiple through via-holes 22 penetrating through the substrate 20 are provided at a position encompassed by the ground wiring 31G in plan view. A back surface electrode 50 is disposed on a back surface on an opposite side of the substrate 20 from the upper surface. The back surface electrode 50 is coupled to the ground wiring 31G through a side surface of the through via-hole 22. The remaining portion in the through via-hole 22 is filled with a conductive filling member 51.

A collector wiring 32C of the second layer is disposed to run parallel to the cell row of the multiple cells 27 in plan view. Part of the collector wiring 32C of the second layer overlaps with part of the collector wiring 31C of the first layer, and both are coupled to each other at an overlapping portion. A partial region of the collector wiring 32C of the second layer is used as a pad 32P for wire bonding.

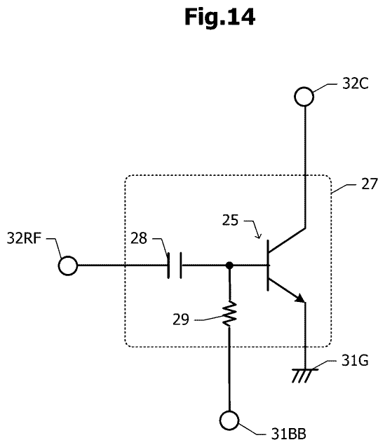

FIG. 14 is an equivalent circuit diagram of the one cell 27. Each of the cells 27 includes the transistor 25, the input capacitor 28, and the ballast resistance element 29. An emitter of the transistor 25 is coupled to the ground wiring 31G and a collector is coupled to the collector wiring 32C. Power is supplied from the collector wiring 32C to the transistor 25.

A base of the transistor 25 is coupled to the radio frequency signal input wiring 32RF via the input capacitor 28. A radio frequency signal is input to the base of the transistor 25 from the radio frequency signal input wiring 32RF via the input capacitor 28. The base of the transistor 25 is further coupled to the base bias wiring 31BB via the ballast resistance element 29. A base bias is supplied from the base bias wiring 31BB to the base of the transistor 25 via the ballast resistance element 29.

Next, excellent effects of the fifth embodiment will be described.

In the fifth embodiment, each of the multiple cells 27 includes transistor 25 having the same configuration as that of the semiconductor device of any of the first to fourth embodiments, so that the breakdown withstand voltage can be made higher and lowering in gain due to the collector-base junction capacitance Cbc can be mitigated, as in the semiconductor device of the first to fourth embodiments.

### Sixth Embodiment

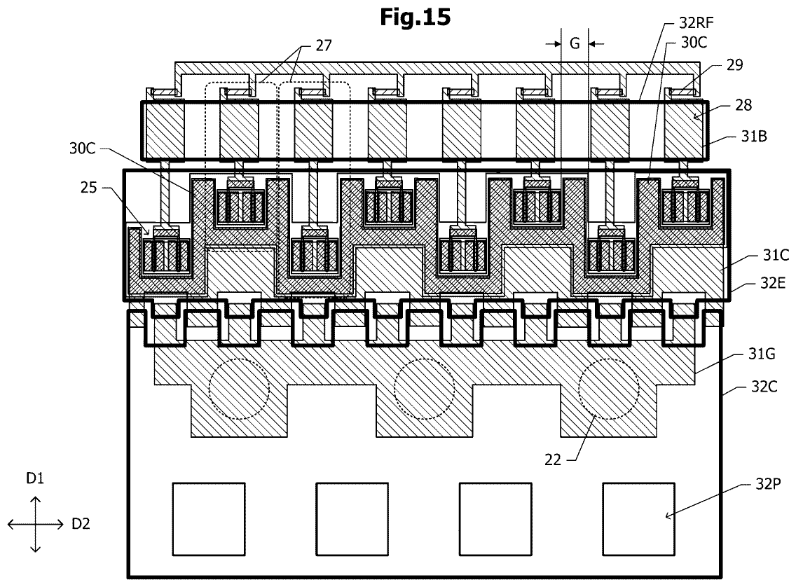

Next, a radio frequency power amplifier according to a sixth embodiment will be described with reference to FIG. 15. Hereinafter, a description of the common configuration with the radio frequency power amplifier according to the fifth embodiment described with reference to FIG. 12 to FIG. 14 will be omitted.

FIG. 15 is a diagram illustrating a disposition of constituent elements of the radio frequency power amplifier according to the sixth embodiment in plan view. In FIG. 15, as in FIG. 12, an electrode in contact with a semiconductor region is hatched with relatively dark lines rising to the right, a wiring of a first layer is hatched with relatively light lines falling to the right, and an outline of a wiring of a second layer is indicated by a relatively thick solid line. In the fifth embodiment (FIG. 12), the respective transistors 25 of the multiple cells 27 are disposed on one straight line parallel to the second direction D2. In contrast, in the sixth embodiment, the respective transistors 25 of the multiple cells 27 are disposed in a staggered manner.

Next, a disposition in a staggered manner will specifically be described. When the multiple cells 27 are consecutively numbered from 1, from the cell 27 at one end in the second direction D2 to the cell 27 at the other end, the transistors 25 of the odd-numbered cells 27 are disposed on one straight line parallel to the second direction D2 and the transistors 25 of the even-numbered cells 27 are disposed on another straight line parallel to the second direction D2. Note that, the transistors 25 of the even-numbered cells 27 are disposed at a position shifted in the first direction D1 relative to the transistors 25 of the odd-numbered cells 27. For example, when viewed from the collector wiring 32C of the second layer, the transistors 25 of the even-numbered cells 27 are disposed at positions farther than the transistors 25 of the odd-numbered cells 27. A shift amount of the transistors 25 of the even-numbered cells 27 in the first direction D1 relative to the transistors 25 of the odd-numbered cells 27 is equal to or larger than a dimension of the collector mesa 26 (FIG. 1A, FIG. 9A, or the like) of each of the transistors 25 in the first direction D1.

A dimension in the second direction D2 (hereinafter, may be referred to as width) of the collector electrode 30C of the transistor 25, farther from the collector wiring 32C of the second layer, is slightly smaller than a distance G in the second direction D2 between the two transistors 25 adjacent to each other in a direction oblique to the second direction D2, and is sufficiently larger than a half of the distance G. A width of the collector wiring 31C of the first layer which substantially overlaps with the collector electrode 30C in plan view is also substantially the same as the width of the collector electrode 30C.

The collector wiring 31C of the first layer is disposed in substantially the entire region between the transistors 25 adjacent to each other in the second direction D2, among the transistors 25 closer to the collector wiring 32C of the second layer.

Next, excellent effects of the sixth embodiment will be described.

In the sixth embodiment, as in the fifth embodiment, the breakdown withstand voltage can be made higher, and lowering in gain due to the collector-base junction capacitance Cbc can be mitigated. In the sixth embodiment, distribution density of the transistors 25 is lower than that in the fifth embodiment. As a result, heat dissipation from the transistor 25 can be increased.

In the fifth embodiment (FIG. 12), the collector wiring 31C disposed between the two transistors 25 adjacent to each other in the second direction D2 is shared by the two transistors 25. As a result, it can be considered that a portion through which the collector current of the one transistor 25 flows is substantially limited to a region of one half of the width of the collector wiring 31C disposed between the two transistors 25.

In contrast, in the sixth embodiment, only the collector current of the one transistor 25 flows through the collector wiring 31C disposed at a position sandwiching the transistor 25, farther from the collector wiring 32C of the second layer, in the second direction D2. As a result, the width of the collector wiring 31C, disposed for the transistor 25 farther from the collector wiring 32C of the second layer, is substantially enlarged.

Further, for the transistors 25 closer to the collector wiring 32C of the second layer, the collector wiring 31C of the first layer is disposed in substantially an entire region between the two transistors 25 adjacent to each other in the second direction D2. As a result, it can be considered that the width of the collector wiring 31C disposed for the transistors 25 closer to the collector wiring 32C of the second layer is sufficiently large.

As described above, in the sixth embodiment, the width of the collector wiring 31C disposed for each of the multiple transistors 25 is larger than that in the fifth embodiment. As a result, parasitic resistance of the collector wiring 31C can substantially be reduced.

### Seventh Embodiment

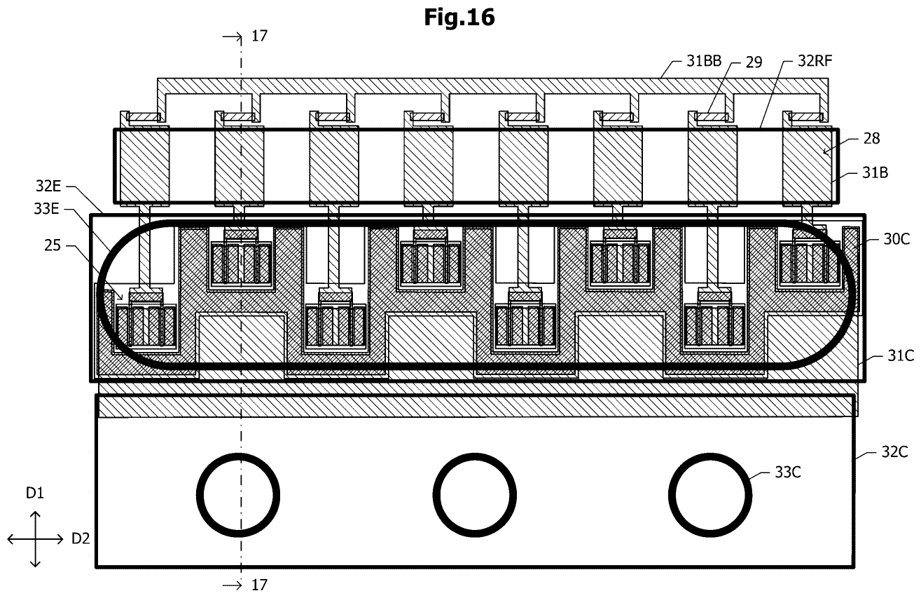

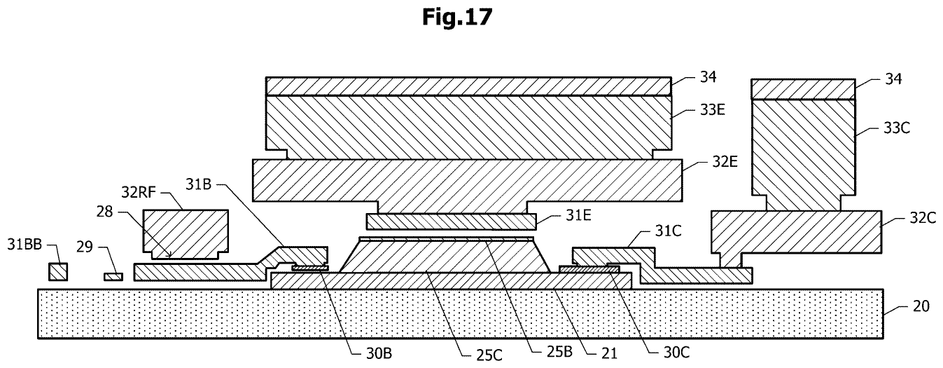

Next, a radio frequency power amplifier according to a seventh embodiment will be described with reference to FIG. 16 and FIG. 17. Hereinafter, a description of the common configuration with the radio frequency power amplifier according to the sixth embodiment described with reference to FIG. 15 will be omitted.

In the sixth embodiment (FIG. 15), the emitter of the transistor 25 is coupled to the back surface electrode 50 disposed on the back surface of the substrate 20, as illustrated in FIG. 13. The pad 32P for wire bonding is disposed on the upper surface of the substrate 20. That is, the radio frequency power amplifier according to the sixth embodiment is mounted on a mounting substrate such that the surface on which the transistor 25 is disposed faces an opposite side of the mounting substrate (face-up mounting). In contrast, the radio frequency power amplifier according to the seventh embodiment is mounted on a mounting substrate such that the surface on which the transistor 25 is disposed faces the mounting substrate (face-down mounting).

FIG. 16 is a diagram illustrating a disposition of constituent elements of the radio frequency power amplifier according to the seventh embodiment in plan view. FIG. 17 is a sectional view taken along a dashed-and-dotted line 17-17 in FIG. 16. In FIG. 16, as in FIG. 15, an electrode in contact with a semiconductor region is hatched with relatively dark lines rising to the right, a wiring of a first layer is hatched with relatively light lines falling to the right, and an outline of a wiring of a second layer is indicated by a relatively thick solid line. Further, an outline of an outer coupling terminal disposed on the wiring of the second layer is represented by a thicker solid line.

The emitter wiring 32E of the second layer is disposed so as to encompass the multiple transistors 25 in plan view. The outer coupling terminal 33E for the emitter is disposed on the emitter wiring 32E of the second layer. The outer coupling terminal 33E at least partially overlaps with all the transistors 25 in plan view.

The collector wiring 32C of the second layer is disposed to run parallel to the emitter wiring 32E of the second layer. Part of the collector wiring 32C of the second layer overlaps with part of the collector wiring 31C of the first layer, and both are coupled to each other at an overlapping portion. Multiple outer coupling terminals 33C for the collector are disposed on the collector wiring 31C of the second layer. The solder 34 is disposed on each of the outer coupling terminal 33E for the emitter and the outer coupling terminal 33C for the collector. For example, a Cu pillar bump is used for the outer coupling terminals 33E and 33C. Note that, instead of the Cu pillar bump, an Au bump, a solder ball bump, or the like may be used.

Next, excellent effects of the seventh embodiment will be described.

In the seventh embodiment, as in the sixth embodiment, the breakdown withstand voltage can be made higher, and lowering in gain due to the collector-base junction capacitance Cbc can be mitigated. In the seventh embodiment, the outer coupling terminal 33E for the emitter functions as a heat dissipation path from the transistor 25 to the mounting substrate. As a result, a temperature rise of the transistor 25 during operation can be mitigated.

### Eighth Embodiment

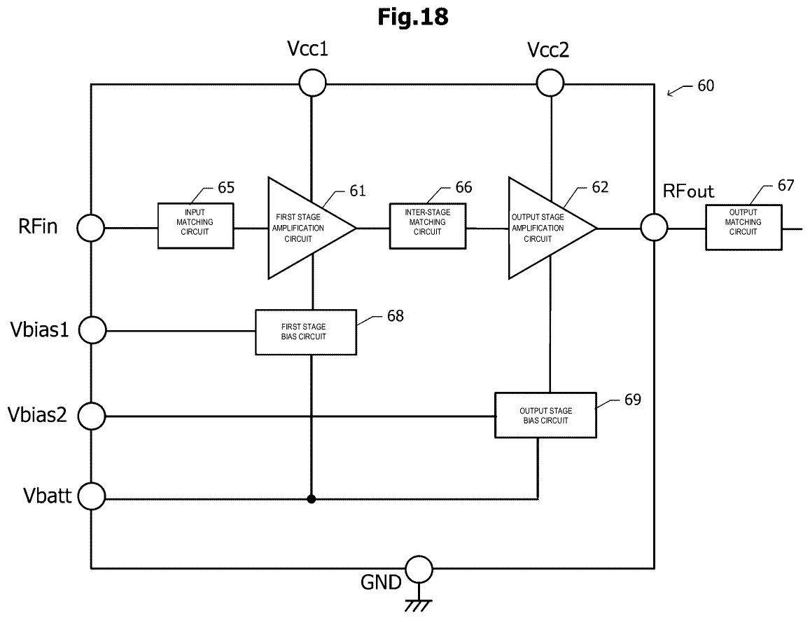

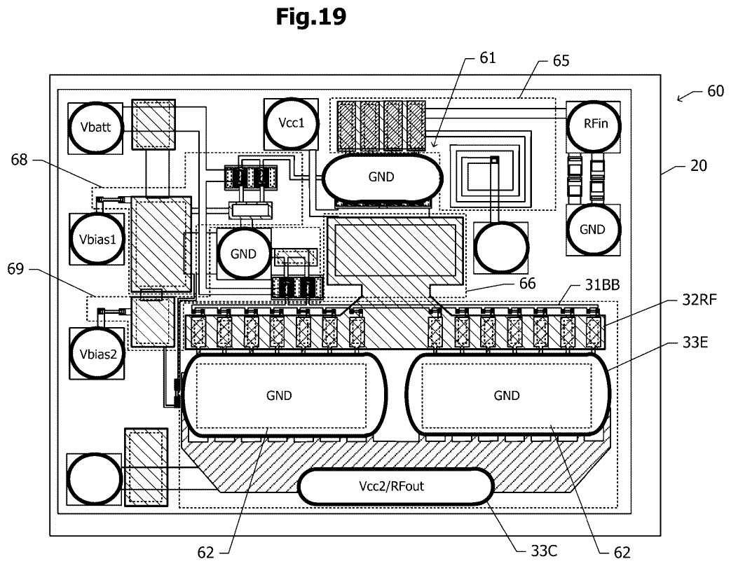

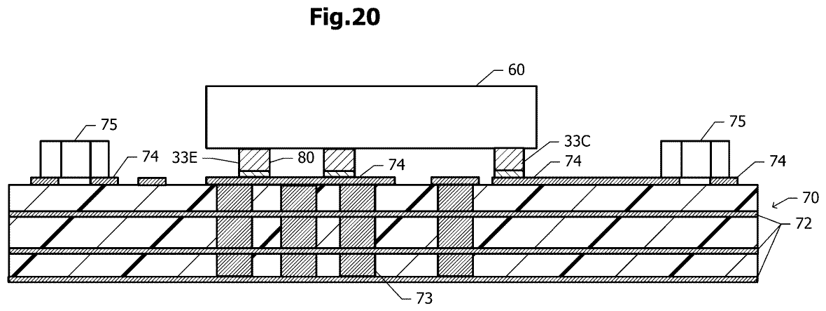

Next, a radio frequency amplification circuit and a radio frequency front-end module according to an eighth embodiment will be described with reference to FIG. 18, FIG. 19, and FIG. 20. The radio frequency amplification circuit according to the eighth embodiment includes the radio frequency power amplifier according to the seventh embodiment (FIG. 16 and FIG. 17).

FIG. 18 is a block diagram of a radio frequency amplification circuit 60 according to the eighth embodiment. The radio frequency amplification circuit 60 according to the eighth embodiment includes a first stage amplification circuit 61, an output stage amplification circuit 62, an input matching circuit 65, an inter-stage matching circuit 66, a first stage bias circuit 68, and an output stage bias circuit 69. The radio frequency amplification circuit 60 according to the eighth embodiment further includes, as outer coupling terminals formed of bumps, a radio frequency signal input terminal RFin, a radio frequency signal output terminal RFout, a first stage bias control terminal Vbias1, an output stage bias control terminal Vbias2, power supply terminals Vcc1 and Vcc2, a bias power supply terminal Vbatt, and a ground terminal GND. Although only one ground terminal GND is illustrated in the block diagram of FIG. 18, multiple ground terminals GND are disposed in an actual case.

A radio frequency signal input from the radio frequency signal input terminal RFin is input to the first stage amplification circuit 61 via the input matching circuit 65. The radio frequency signal amplified by the first stage amplification circuit 61 is input to the output stage amplification circuit 62 via the inter-stage matching circuit 66. The radio frequency signal amplified by the output stage amplification circuit 62 is output from the radio frequency signal output terminal RFout. The radio frequency power amplifier according to the seventh embodiment (FIG. 16 and FIG. 17) is used for the output stage amplification circuit 62. An output matching circuit 67 is coupled to the radio frequency signal output terminal RFout.

A power supply voltage is applied to the first stage amplification circuit 61 and the output stage amplification circuit 62 from the power supply terminals Vcc1 and Vcc2, respectively. A bias power supply is supplied from the bias power supply terminal Vbatt to the first stage bias circuit 68 and the output stage bias circuit 69. The first stage bias circuit 68 supplies a bias to the first stage amplification circuit 61 based on a bias control signal input to the first stage bias control terminal Vbias1. The output stage bias circuit 69 supplies a bias to the output stage amplification circuit 62 based on a bias control signal input to the output stage bias control terminal Vbias2.

FIG. 19 is a diagram illustrating a disposition of constituent elements in a substrate of the radio frequency amplification circuit 60 according to the eighth embodiment. In FIG. 19, the main wirings of the first and second layers are hatched.

The output stage amplification circuit 62 is disposed at a position overlapping with the outer coupling terminal 33E for the emitter. In the seventh embodiment (FIG. 16), one outer coupling terminal 33E is provided for the eight transistors 25, whereas in the eighth embodiment, fourteen transistors 25 are divided into two groups, and the outer coupling terminals 33E are provided for the two groups, respectively. In the seventh embodiment (FIG. 16), the three outer coupling terminals 33C are disposed for the eight transistors 25, whereas in the eighth embodiment, the one outer coupling terminal 33C is disposed for the fourteen transistors 25. The outer coupling terminal 33C corresponds to the power supply terminal Vcc2 (FIG. 18) and the radio frequency signal output terminal RFout (FIG. 18).

On the upper surface of the substrate 20, further disposed are the first stage amplification circuit 61, the input matching circuit 65, the inter-stage matching circuit 66, the first stage bias circuit 68, the output stage bias circuit 69, the radio frequency signal input terminal RFin, the power supply terminal Vcc1, the bias power supply terminal Vbatt, the first stage bias control terminal Vbias1, and the output stage bias control terminal Vbias2. Further, disposed are a ground terminal GND coupled to the emitters of the multiple transistors included in the first stage amplification circuit 61, and the like.

FIG. 20 is a schematic sectional view of the radio frequency front-end module according to the eighth embodiment. The outer coupling terminal 33E for the emitter, the outer coupling terminal 33C for the collector, and the like are disposed on one surface of the radio frequency amplification circuit 60. Multiple lands 74 are disposed on a mounting surface of a module substrate 70. The outer coupling terminals 33E and 33C of the radio frequency amplification circuit 60 are coupled to the lands 74 of the module substrate 70 by solder 80, respectively.

In addition to the outer coupling terminals 33E and 33C, multiple outer coupling terminals for power supply and signals (FIG. 19) are disposed in the radio frequency amplification circuit 60. The outer coupling terminals above are also coupled to corresponding lands of the module substrate 70 by solder, respectively.

In addition to the radio frequency amplification circuit 60, multiple surface mount devices 75 such as an inductor, a capacitor, and the like are mounted on the mounting surface of the module substrate 70. Some of the surface mount devices 75 above constitute the output matching circuit 67 (FIG. 18). A ground plane 72 is disposed in an inner layer and on a surface (hereinafter, referred to as back surface) on an opposite side of the mounting surface of the module substrate 70. Provided are multiple vias 73 extending from the lands 74 for the ground disposed on the mounting surface to the ground plane 72 on the back surface.

Next, excellent effects of the eighth embodiment will be described.

In the eighth embodiment, the radio frequency amplification circuit according to the seventh embodiment (FIG. 16 and FIG. 17) is used for the output stage amplification circuit 62 (FIG. 18) of the radio frequency amplification circuit 60. As a result, as in the fifth embodiment, the breakdown withstand voltage of the transistor 25 of the output stage amplification circuit 62 can be made higher, and lowering in gain due to the collector-base junction capacitance Cbc can be mitigated.

The above-described embodiments are merely examples, and it is needless to say that partial replacement or combination of the configurations illustrated in different embodiments is possible. The same operation and effect by the same configuration of the multiple embodiments are not described for each embodiment. Furthermore, the present disclosure is not limited to the embodiments described above. For example, it will be obvious to those skilled in the art that various modifications, improvements, combinations, and the like are possible.

What is claimed is:

1. A semiconductor device, comprising:
a substrate;
a transistor including a collector layer, a base layer, and an emitter layer that are laminated in order on an upper surface being one side surface of the substrate;
four or more emitter electrodes electrically coupled to the emitter layer;
a base electrode including two or more base fingers electrically coupled to the base layer; and
a collector electrode electrically coupled to the collector layer,
wherein
the emitter electrodes and the base fingers each have a shape elongated in a first direction in the upper surface of the substrate,
the emitter electrode and the base finger are side by side in a second direction orthogonal to the first direction in the upper surface of the substrate,
emitter electrodes are respectively at both ends in the second direction of a row in which the four or more emitter electrodes and the two or more base fingers that are side by side in the second direction,
an inter-base finger region is a region between the two base fingers adjacent to each other in the second direction, and the two emitter electrodes being side by side in the second direction are in at least the one inter-base finger region, and
when a ratio of an area of the emitter electrode in plan view to a length of an edge of the emitter electrode facing the one or two base fingers that are adjacent to each of multiple of the multiple electrodes is defined as an area to facing length ratio, a difference between a maximum value and a minimum value of the area to facing length ratio of each of the multiple emitter electrodes is 20% or less of an average value of the area to facing length ratio.

2. The semiconductor device according to claim 1,
wherein the four or more emitter electrodes have the same area in plan view.

3. A semiconductor device, comprising:
a transistor including a collector layer, a base layer, and an emitter layer laminated in order on an upper surface being one side surface of a substrate;
three emitter electrodes electrically coupled to the emitter layer;
a base electrode including two base fingers electrically coupled to the base layer; and
a collector electrode electrically coupled to the collector layer,
wherein
the emitter electrodes and the base fingers each have a shape elongated in a first direction in the upper surface of the substrate,
the three emitter electrodes and the two base fingers are disposed in a second direction orthogonal to the first direction in the upper surface of the substrate in an order of the emitter electrode, the base finger, the emitter electrode, the base finger, and the emitter electrode,
when a ratio of an area of the emitter electrode in plan view to a length of an edge of the emitter electrode facing the one or two base fingers disposed adjacent to each of multiple of the emitter electrodes is defined as an area to facing length ratio, a difference between a maximum value and a minimum value of the area to facing length ratio of each of the multiple emitter electrodes is 20% or less of an average value of the area to facing length ratio, and
in plan view, a ratio of a dimension in the second direction to a dimension in the first direction of a minimum encompassing rectangle that encompasses the three emitter electrodes is from 0.5 to 2.

4. The semiconductor device according to claim 1, wherein
in plan view, the collector electrode surrounds a row of the emitter electrodes and the base fingers which are side by side in the second direction in a U-shape, on both sides in the second direction and one side in the first direction.

5. The semiconductor device according to claim 1, wherein
in plan view, the base electrode couples the multiple base fingers to each other in an outer side portion of a junction interface between the base layer and the collector layer.

6. The semiconductor device according to claim 1, wherein
a number of the base fingers is two, and
in plan view, a ratio of a dimension in the second direction to a dimension in the first direction of a minimum encompassing rectangle encompassing the multiple emitter electrodes is from 0.5 to 2.

7. The semiconductor device according to claim 1, wherein
the transistor is a heterojunction bipolar transistor.

8. A radio frequency power amplifier, comprising:
multiple semiconductor devices according to claim 1, disposed side by side in the second direction on the upper surface of the substrate;
an emitter wiring to couple the emitter electrodes of the multiple semiconductor devices;
a radio frequency signal input wiring; and
an input capacitor to couple the base electrode of each of the multiple semiconductor devices and the radio frequency signal input wiring,
wherein the collector electrodes of the multiple semiconductor devices are continuous with each other.

9. The radio frequency power amplifier according to claim 8, further comprising:
a back surface electrode on a lower surface on an opposite side of the substrate from the upper surface,
wherein
the substrate includes a through via-hole, and
the back surface electrode is electrically coupled to the emitter wiring through the through via-hole.

10. The radio frequency power amplifier according to claim 8, further comprising:
an outer coupling terminal on the upper surface of the substrate and electrically coupled to the emitter wiring.

11. The semiconductor device according to claim 2, wherein
in plan view, the collector electrode surrounds a row of the emitter electrodes and the base fingers which are side by side in the second direction in a U-shape, on both sides in the second direction and one side in the first direction.

12. The semiconductor device according to claim 2, wherein
in plan view, the base electrode couples the multiple base fingers to each other in an outer side portion of a junction interface between the base layer and the collector layer.

13. The semiconductor device according to claim 2, wherein
a number of the base fingers is two, and
in plan view, a ratio of a dimension in the second direction to a dimension in the first direction of a minimum encompassing rectangle encompassing the multiple emitter electrodes is from 0.5 to 2.

14. The semiconductor device according to claim 2, wherein
the transistor is a heterojunction bipolar transistor.

15. A radio frequency power amplifier, comprising:
the semiconductor devices according to claim 2, disposed side by side in the second direction on the upper surface of the substrate;
an emitter wiring to couple the emitter electrodes of the multiple semiconductor devices;
a radio frequency signal input wiring; and
an input capacitor to couple the base electrode of each of the multiple semiconductor devices and the radio frequency signal input wiring,
wherein the collector electrodes of the multiple semiconductor devices are continuous with each other.

16. The semiconductor device according to claim 3, wherein
in plan view, the collector electrode surrounds a row of the emitter electrodes and the base fingers which are side by side in the second direction in a U-shape, on both sides in the second direction and one side in the first direction.

17. The semiconductor device according to claim 3, wherein
in plan view, the base electrode couples the multiple base fingers to each other in an outer side portion of a junction interface between the base layer and the collector layer.

18. The semiconductor device according to claim 3, wherein
a number of the base fingers is two, and
in plan view, a ratio of a dimension in the second direction to a dimension in the first direction of a minimum encompassing rectangle encompassing the multiple emitter electrodes is from 0.5 to 2.

19. The semiconductor device according to claim 3, wherein
the transistor is a heterojunction bipolar transistor.

20. A radio frequency power amplifier, comprising:
multiple semiconductor devices according to claim 3, disposed side by side in the second direction on the upper surface of the substrate;
an emitter wiring to couple the emitter electrodes of the multiple semiconductor devices;
a radio frequency signal input wiring; and
an input capacitor to couple the base electrode of each of the multiple semiconductor devices and the radio frequency signal input wiring,
wherein the collector electrodes of the multiple semiconductor devices are continuous with each other.
